(19) United States
(12) Patent Application Publication
(10) Pub. No.: US 2026/0132016 A1
(43) Pub. Date: May 14, 2026

(54) PIEZOELECTRIC MICROELECTROMECHANICAL DEVICE WITH ANCHOR REINFORCEMENT

(71) Applicant: QUALCOMM Incorporated, San Diego, CA (US)

(72) Inventors: Robert John LITTRELL, Belmont, MA (US); Hamid BASAERI, Medford, MA (US); Jong Soo CHOI, Waltham, MA (US); Jeroen BIELEN, Mook (NL); Kun GAO, Helmond (NL)

(21) Appl. No.: 19/246,447

(22) Filed: Jun. 23, 2025

Related U.S. Application Data
(60) Provisional application No. 63/718,215, filed on Nov. 8, 2024.

(51) Int. Cl. B81B 3/00; B81C 1/00

(52) U.S. Cl. CPC B81B 3/0078; B81C 1/00666; B81B 2201/0257; B81B 2203/0118; B81B 2203/0307; B81B 2203/0323; B81B 2203/04

(57) ABSTRACT

Aspects of the disclosure relate to piezoelectric microelectromechanical systems (MEMS) devices. A piezoelectric MEMS device may include a transducer body including an acoustic cavity extending from a bottom surface to a top surface; a piezoelectric cantilever disposed over the top surface and including a lever region and a sensing region; and an anchor reinforcement member disposed over the piezoelectric cantilever and the transducer body.

### CROSS-REFERENCE TO RELATED APPLICATION

This application claims the benefit of U.S. Provisional Application No. 63/718,215, filed Nov. 8, 2024, which is hereby incorporated by reference, in its entirety and for all purposes.

### TECHNICAL FIELD

This disclosure relates generally to acoustic transducers, and more specifically to piezoelectric microelectromechanical systems (MEMS) devices with anchor reinforcement.

### BACKGROUND

Microelectromechanical system (MEMS) devices can be used in a variety of contexts. Piezoelectric MEMS devices, for example, can be used as transducers.

An example of a MEMS acoustic transducer is a MEMS microphone, which converts sound pressure into an electrical voltage. Based on their transduction mechanisms, MEMS microphones can be made in various forms, such as capacitive microphones or piezoelectric microphones.

MEMS capacitive microphones and electric condenser microphones (ECMs) currently dominate the consumer electronics market for microphones. Piezoelectric MEMS microphones, however, occupy a growing portion of the consumer market, and have unique advantages compared to their capacitive counterparts. Among other things, piezoelectric MEMS microphones do not require a back plate, eliminating the squeeze film damping, which is an intrinsic noise source for capacitive MEMS microphones. In addition, piezoelectric MEMS microphones are reflow-compatible and can be mounted to a printed circuit board (PCB) using typical lead-free solder processing, which could irreparably damage typical ECMs.

Manufacturers of MEMS devices have taken a variety of approaches to improve device performance.

### SUMMARY

Aspects of the present disclosure describe devices, systems, and methods for fabrication of piezoelectric microelectromechanical system (MEMS) devices. According to at least one illustrative example, an acoustic transducer is provided. The acoustic transducer includes: a transducer body including an acoustic cavity extending from a bottom surface to a top surface; a piezoelectric cantilever disposed over the top surface and including a lever region and a sensing region; and an anchor reinforcement member disposed over the piezoelectric cantilever and the transducer body

In some aspects, an apparatus is provided. The apparatus includes: a MEMS transducer for generating an electrical signal based on acoustic signals, wherein the MEMS transducer includes: a transducer body including an acoustic cavity extending from a bottom surface to a top surface; a piezoelectric cantilever disposed over the top surface and including a lever region and a sensing region; and an anchor reinforcement member disposed over the piezoelectric cantilever and the transducer body.

In some aspects, an acoustic transducer is provided. The acoustic transducer includes a substrate having a top surface and forming an acoustic cavity; a piezoelectric electroacoustic structure including at least one cantilever beam with a base coupled to the top surface of the substrate and extending over the acoustic cavity, the cantilever beam formed from a layer stack comprising one or more alternating electrode layers and piezoelectric layers; and a layer of ductile material disposed on or above the piezoelectric electroacoustic structure and disposed over the top surface of the substrate and extending partially over the acoustic cavity.

In some aspects, one or more of the apparatuses described above is, is part of, or includes a mobile device (e.g., a mobile telephone or so-called “smart phone” or other mobile device), a wearable device, an extended reality device (e.g., a virtual reality (VR) device, an augmented reality (AR) device, or a mixed reality (MR) device), a personal computer, a laptop computer, a server computer, a vehicle (e.g., a computing device of a vehicle), or other device. In some aspects, an apparatus includes a camera or multiple cameras for capturing one or more images. In some aspects, the apparatus includes a display for displaying one or more images, notifications, and/or other displayable data. In some aspects, the apparatus can include one or more sensors. In some cases, the one or more sensors can be used for determining a location and/or pose of the apparatus, a state of the apparatuses, and/or for other purposes.

This summary is not intended to identify key or essential features of the claimed subject matter, nor is it intended to be used in isolation to determine the scope of the claimed subject matter. The subject matter should be understood by reference to appropriate portions of the entire specification of this patent, any or all drawings, and each claim.

The foregoing, together with other features and embodiments, will become more apparent upon referring to the following specification, claims, and accompanying drawings.

### BRIEF DESCRIPTION OF DRAWINGS

FIG. 1 illustrates a microelectromechanical systems (MEMS) transducer including an anchor reinforcement member in accordance with aspects described herein;

FIG. 2 illustrates aspects of a MEMS sensor in accordance with aspects described herein;

FIG. 3 illustrates aspects of a piezoelectric MEMS sensor in accordance with aspects described herein;

FIG. 4A illustrates a plan view of a MEMS piezoelectric transducer in accordance with some aspects of the disclosure;

FIG. 4B illustrates a cross-sectional view of a MEMS piezoelectric transducer in accordance with some aspects of the disclosure;

FIG. 5 is a perspective view of a cross-section of a piezoelectric MEMS system sensor in accordance with some aspects of the disclosure;

FIG. 6 illustrates an enlarged view of the boundary region between a side surface and a piezoelectric cantilever in accordance with some aspects of the disclosure;

FIG. 7 illustrates a plan view of a piezoelectric cantilever including an anchor reinforcement in accordance with some aspects of the disclosure;

FIG. 8 illustrates a method for manufacturing piezoelectric devices in accordance with aspects described herein; and

FIG. 9 is a block diagram of a computing device that can include a MEMS device in accordance with aspects described herein.

Like reference symbols in the various drawings indicate like elements.

### DETAILED DESCRIPTION

The detailed description set forth below in connection with the appended drawings is intended as a description of example aspects and implementations and is not intended to represent the only implementations in which the invention may be practiced. The detailed description includes specific details for the purpose of providing a thorough understanding of the example aspects and implementations. In some instances, some devices are shown in block diagram form. Drawing elements that are common among the following figures may be identified using the same reference numerals.

Piezoelectric devices operate using the piezoelectric effect, where mechanical stress in a piezoelectric material generates an electrical charge. The electrical charge can be converted into a voltage by adding electrodes. Piezoelectric devices can operate as transducers for converting electrical energy into sound waves. In some cases, piezoelectric devices can operate as transducers for converting mechanical energy from acoustic waves into electrical energy.

Microelectromechanical system (MEMS) piezoelectric devices are manufactured using semiconductor processes and result in remarkably small products. Their compact size allows piezoelectric devices to be embedded in tiny sensors, wearable devices, and even medical implants without significantly impacting the design or weight of these devices and are used in devices that require energy harvesting or precise actuation in limited spaces. For example, piezoelectric devices are commonly used in mobile phones, industrial equipment, and biomedical instruments because they are highly responsive, energy-efficient, and small in size.

In some aspects, a piezoelectric device can include microelectromechanical components that are configured to respond to mechanical forces such as an acoustic signal or acoustic pressure. A piezoelectric device may include at least one piezoelectric cantilever that deforms due to the applied mechanical force. In some cases, the piezoelectric device may undergo reliability testing that strains various components to maximum effect to determine the reliability of these components. One example reliability test includes an air gun test that injects pressurized air into an acoustic cavity of a device. Another example reliability test is a drop test, which drops the device onto a hard surface and causes a large acoustic pressure to be applied into the acoustic cavity. In each of these tests, the pressure causes the piezoelectric cantilever to deform.

In some aspects, the anchor reinforcement is positioned partially over the top surface of the transducer close to the location of the anchor. The anchor reinforcement is configured to mechanically distribute stress applied to the piezoelectric cantilever at an anchor region. In conventional cases, the mechanical stresses may focus on a hard edge between the piezoelectric cantilever and the side surface of the released area. The anchor reinforcement is configured to spread the stress across the surface area and reduce the concentration of stress at the hard edge. In some cases, the reliability of the piezoelectric cantilever increases based on the configuration of the anchor reinforcement. In some aspects, the anchor reinforcement is a ductile material as compared to the piezoelectric cantilever. For example, the anchor reinforcement includes a sufficiently thin metal layer. A thick layer with too much metal may become too rigid.

Additional details associated with such device structures and improved device performance are provided below with respect to the figures.

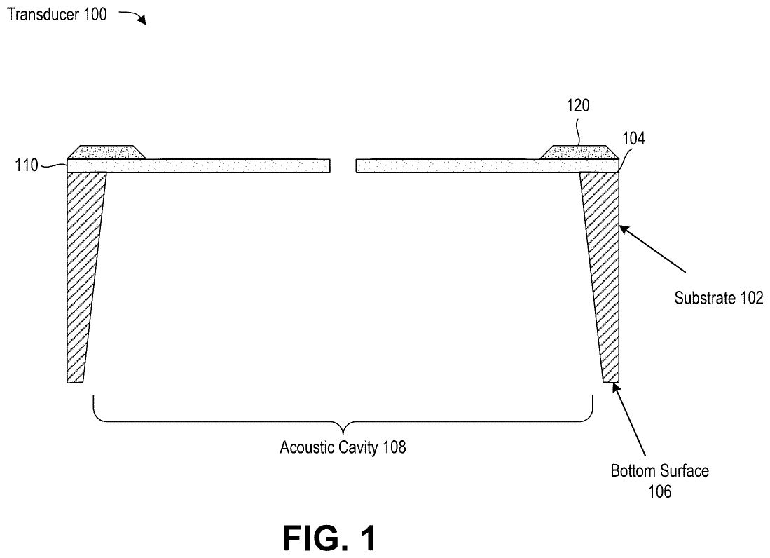

FIG. 1 illustrates a MEMS transducer 100 including an anchor reinforcement 120 in accordance with aspects described herein. The MEMS transducer 100 includes a substrate 102 (e.g., a semiconductor substrate such as silicon (Si)) having a top surface 104 and a bottom surface 106. An acoustic cavity 108 is formed through the substrate 102, with the acoustic cavity 108 bounded by an aperture in the top surface 104 and an aperture in the bottom surface 106. An electroacoustic structure 110 is formed at or above the top surface 104 and an aperture of the top surface 104. The electroacoustic structure 110 includes an acoustic layer (e.g., a piezoelectric layer) to receive acoustic vibrations passing through the acoustic cavity 108 and transduce the vibrations (e.g., sound) into an electrical signal via the electroacoustic structure 110.

In one aspect, the electroacoustic structure 110 includes a piezoelectric structure configured to convert mechanical energy into electrical energy. For example, the acoustic cavity 108 receives physical energy (e.g., acoustic signals) through the electroacoustic structure 110 and displaces (e.g., vibrates) based on the physical energy. The vibrations applied to the acoustic cavity 108 may be converted into electrical energy based on the piezoelectric effect. The piezoelectric effect is the ability of certain materials (e.g., quartz) to generate an electric charge in response to an applied mechanical stress. For example, a voltage can be generated based on providing an acoustic signal into the electroacoustic structure 110.

In some aspects, the energy produced by the electroacoustic structure 110 is based on the mechanical stress captured at an electrode. When a piezoelectric material (e.g., the electroacoustic structure 110) is compressed, the piezoelectric material generates a charge proportional to the applied force based on an electrode disposed within the area occupied by the electrode. For example, the generated electrical charge, the geometry of the electrode, and the piezoelectric material properties determine the generated voltage.

That is, in the electroacoustic structure 110, as capacitance increases, the voltage decreases for a constant charge. Maximizing voltage is important because the signals are amplified, and lower voltage can introduce various noises (e.g., thermal noise) that affect the performance of the MEMS transducer 100. For example, higher voltage directly translates into higher signal-to-noise ratio (SNR) performance by minimizing the effects of noise.

In some aspects, the electroacoustic structure 110 includes a plurality of piezoelectric cantilevers that are configured to cover the acoustic cavity 108. The piezoelectric cantilevers are attached to the top surface 104 and are configured to respond to acoustic pressure. Based on the acoustic pressure, each piezoelectric cantilever generates an electrical signal.

In some aspects, the piezoelectric cantilevers can each include an anchor reinforcement 120 that is configured to distribute stress across an anchor region. For example, the anchor reinforcement 120 is configured as a ductile material over the base of a piezoelectric cantilever. The anchor reinforcement 120 extends over a support portion of the base of the piezoelectric cantilever that is attached to the top surface 104 of the substrate 102.

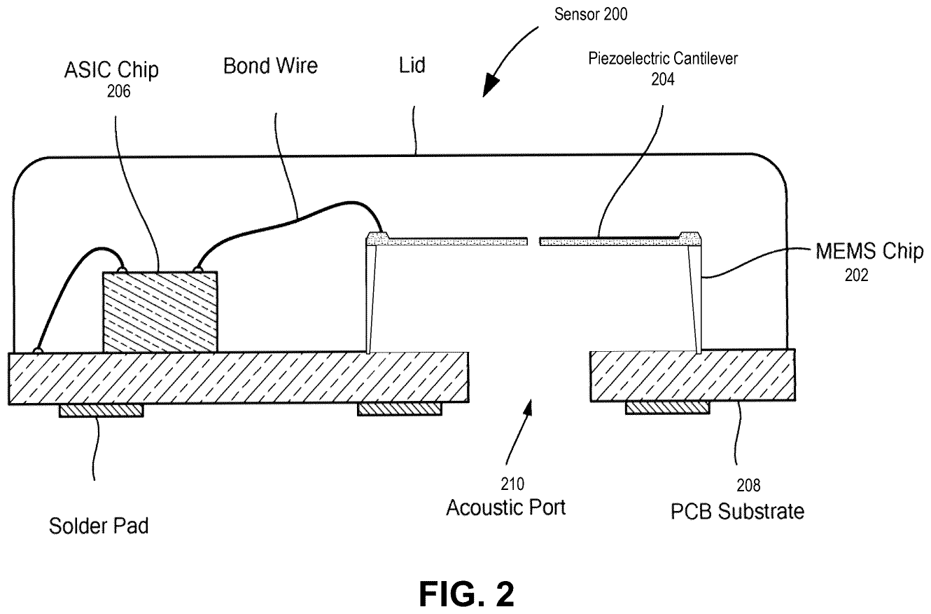

FIG. 2 illustrates aspects of a MEMS sensor 200 in accordance with aspects described herein. The MEMS sensor 200 includes a MEMS chip 202 having a transducer. The transducer may include a plurality of piezoelectric cantilevers 204 for generating electrical signals based on acoustic signals applied to the MEMS sensor. Additionally, the MEMS sensor 200 includes a lid, an application specific integrated circuit (ASIC) chip 206, and a printed circuit board (PCB) substrate 208. As shown by FIG. 2, transducers (e.g., the MEMS transducer 100 of FIG. 1) can be implemented on a MEMS chip 202 formed using a substrate (e.g., substrate 102 in FIG. 1). In some aspects, the MEMS chip 202 can include multiple transducers or other devices (not shown) in addition to the acoustic MEMS transducer. The sensor 200 includes an acoustic port 210 formed in the PCB substrate 208, and the PCB substrate 208 supports the MEMS chip 202 and the ASIC chip 206. The acoustic port 210 is aligned with a bottom aperture of the acoustic cavity in the substrate (e.g., the acoustic cavity 108 in FIG. 1) of the MEMS chip 202. In other implementations, other such configurations of the acoustic port 210 can be used so long as a path for acoustic pressure to reach the electroacoustic structures (e.g., the piezoelectric cantilevers) is present.

The ASIC chip 206 and the MEMS chip 202 may connected by an interconnect such as bond wires. In some aspects, rather than implement the system with two separate chips, some variants may implement both the MEMS chip 202 and the ASIC chip 206 as part of the same die. Accordingly, illustration of separate chips is for illustrative purposes only. In addition, in other embodiments the ASIC chip 206 may be implemented on a die in a separate package with one or more interconnects electrically coupling the MEMS chip 202 to the ASIC chip 206.

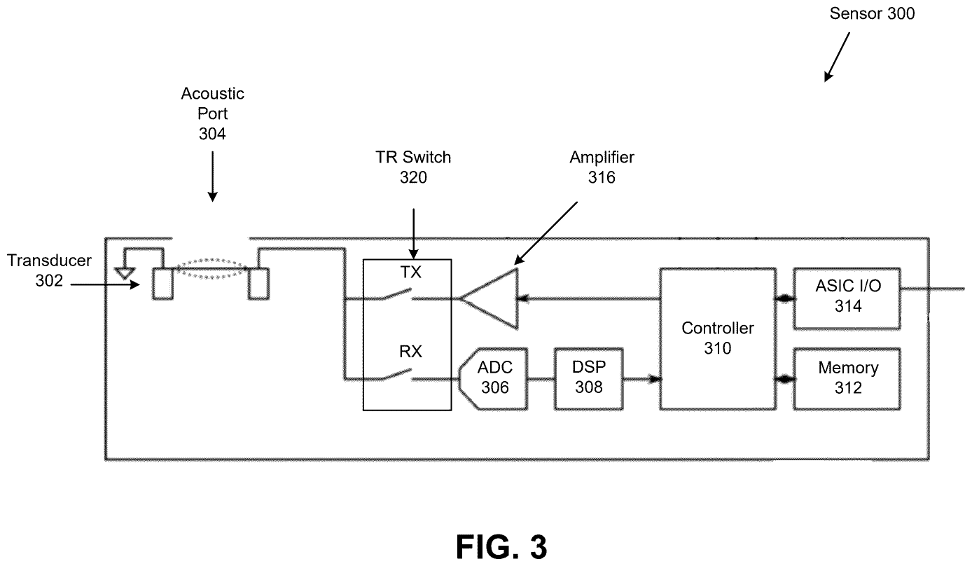

FIG. 3 illustrates aspects of a piezoelectric MEMS sensor 300 in accordance with aspects described herein. The sensor 300 includes a piezoelectric MEMS transducer 302 that interfaces with an acoustic port 304 for receiving acoustic signals. For example, the piezoelectric MEMS transducer 302 can be implemented on a MEMS chip (e.g., the MEMS chip 202 of FIG. 2). An output of the piezoelectric MEMS transducer 302 is coupled to an analog-to-digital converter (ADC) 306, which accepts an analog signal from the output of the transducer and converts the analog signal (e.g., which is a transduced signal from motion vibrations detected at the transducer 1) to a digital signal. An output of the ADC 306 is provided to a digital signal processor (DSP) 308, which can perform preprocessing, digital filtering, or other signal conditioning on the information from the transducer and provide an output signal to a controller 310. The controller 310 can further process the information from the transducer to generate a digital data signal corresponding to the analog signal output from the transducer 1. The digital data signal can be stored in a memory 312 on the sensor 300 or can be output to a data path via ASIC input/output (i/o) circuitry 314.

The acoustic port 304 is aligned with an acoustic port of the piezoelectric MEMS transducer 302 (e.g., the acoustic cavity 108 in FIG. 1). The piezoelectric MEMS sensor 300 allows acoustic signals to be received by the piezoelectric MEMS transducer 302 in a receive mode and generate electrical signals. In some cases, the sensor 300 can allow acoustic waves to be transmitted from the piezoelectric MEMS transducer 302 in an acoustic signal output mode. In this case, the piezoelectric MEMS sensor 300 may include amplifier 316, and the controller 310 may control the piezoelectric MEMS sensor 300 to select between receive (e.g., acoustic signal input) and transmit (e.g., acoustic signal output) modes (e.g., using Transmit-Receive (TR) switch 320).

For example, in a transmit mode, an electrical signal (e.g., a pulse width modulated (PWM) signal, a digital signal, etc.) is received by the ASIC I/O 314 and provided to the controller 310. The electrical signal is modified by the controller 310 (e.g., filtering, and shaping for the transducer) and provided to an amplifier 316.

In a receive mode, the piezoelectric MEMS transducer 302 receives incident acoustic waves via the acoustic port 304 and converts the acoustic signals into electrical signals (e.g., a continuous wave voltage). The ADC 306 and the DSP 308 convert the analog electrical signal from the piezoelectric MEMS transducer 302 to a format acceptable to the controller 310, which can either store the signal in memory 312 or transmit the signal to additional processing circuitry of a larger device via the ASIC I/O 314. For example, the MEMS transducer 302 can be integrated into a wireless earbud, which may provide the acoustic signal to a wireless device (e.g., a phone, a laptop, etc.).

In some aspects, in a transmission mode, an electrical signal is provided from the ASIC I/O 314 to the controller 310. The electrical signal may be filtered by the controller 310 to shape the signal based on the piezoelectric MEMS transducer 302. The electrical signal may be converted into an analog electrical signal at the controller 310 and provided to the amplifier 316 to boost the power of the analog electrical signal. The amplifier 316, as part of transmission operations, can perform additional waveform conditioning and amplification (e.g., via a power amplifier). The piezoelectric MEMS transducer 302 receives the analog signal and generates an acoustic signal. In some cases, the amplifier 316 may be omitted, such as when the analog signal has sufficient power for acoustic transmission.

In some aspects, multiple separate sensor packages having MEMS acoustic transducers with overstress protection can be included in a single device. In other aspects, a shared package can be used for multiple transducers (e.g., on a shared PCB substrate such as the PCB substrate 208 with the same lid).

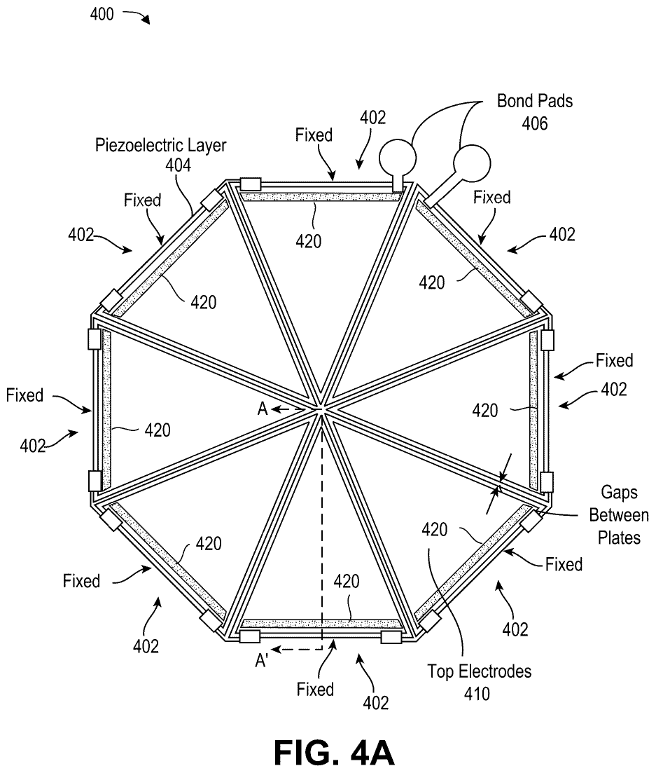

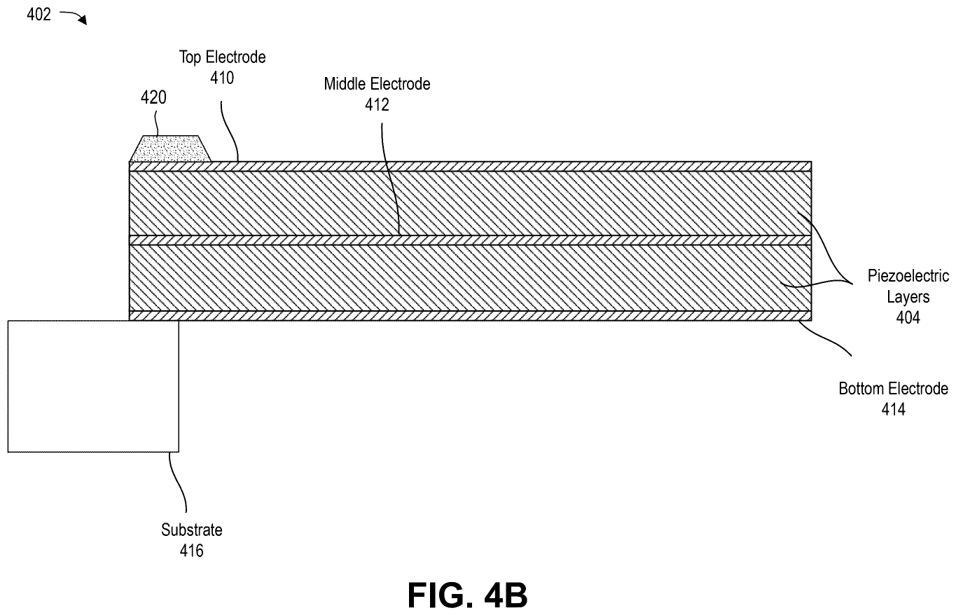

FIG. 4A illustrates a plan view of a MEMS piezoelectric transducer 400 in accordance with some aspects of the disclosure. The MEMS piezoelectric transducer 400 includes a plurality of piezoelectric cantilevers 402 that are configured to cover a cavity (e.g., the acoustic cavity 108 in FIG. 1). The piezoelectric cantilever 402 includes an associated length that is determined by the line segment from the tip of the central end that is perpendicular to the fixed end, and the line segment extends from the fixed end at the substrate to the tip of the central end. As described above, when sound vibrations impact a surface of the deflection beams, the cantilevered beams will move due to the pressure (e.g., z direction movement in and out of the x-y plane illustrated in FIG. 4A). The movement in and out of this plane is referred to herein as vertical deflection. The deflection at the fixed end will be less than the deflection at the central end, with the amount of deflection increasing along the distance of the line segment away from the substrate toward the tip of the central end. The electrodes that generate the electrical signals at the bond pads 406 in response to the acoustic vibrations on the piezoelectric cantilevers 402 can add rigidity to the piezoelectric cantilever 402, and so in some implementations, placement of the top electrodes 410 can be limited to a space approximately two-thirds of the line segment distance from the fixed attachment to the substrate at the fixed end towards the tip of the central end (e.g., limited to a fixed end). For example, the stress and therefore the signal generated by the piezoelectric cantilevers 402 is concentrated in a base portion of the top electrodes 410. In some implementations, an electrode layer can cover a surface or x-y plane cross-section of the entire illustrated fixed end of each of the cantilevered beams. In other implementations, smaller electrode shapes can be used in a portion of the fixed end of each of the piezoelectric cantilevers 402. In some aspects, the central end of each of the cantilevered beams does not include electrode layers. In some aspects, the electrode layers do not extend to the tip of the central end (e.g., the free movement end) of each piezoelectric cantilever 402 to avoid sensing free end movement in the deflection end (e.g., where the signal which is proportional to the stress in the cantilever).

Other aspects of a piezoelectric MEMS acoustic transducer may use more or fewer piezoelectric cantilevers 402. Accordingly, as with other features, the discussion of eight piezoelectric cantilevers 402 is for illustrative purposes only. The piezoelectric cantilevers 402 are fixed at their respective bases and are configured to freely move around their fixed ends as part of acoustic layer operation in response to incoming/incident sound pressure (e.g., an acoustic wave). In some cases, piezoelectric cantilevers 402 configured as triangles provide a benefit over rectangular cantilevers and can be more simply configured to form a gap controlling geometry by separating an acoustic port on one side of the cantilevers of the piezoelectric MEMS acoustic transducer from an air pocket on the other side of the cantilevers. Specifically, when the piezoelectric cantilevers 402 bend up or down due to either sound pressure or residual stress, the gaps between adjacent piezoelectric cantilevers 402 remain relatively small and uniform in the example symmetrical shapes with fixed ends using the piezoelectric cantilevers 402.

In some cases, the top electrodes 410 are electrically connected in series to achieve the desired capacitance and sensitivity values. In addition to the top electrodes 410, the rest of the piezoelectric cantilever 402 also may be covered by metal to maintain certain mechanical strength of the structure. For example, in some implementations, the middle electrodes 412 may be covered in metal. In some cases, the middle electrodes 412 may not contribute to the electrical signal of the microphone output. In some aspects, a MEMS acoustic transducer can include piezoelectric cantilevers 402 without middle electrodes 412.

As described above, as a piezoelectric cantilever 402 bends or flexes around the fixed end as part of acoustic layer operation, the top electrodes 410 and/or the middle electrodes 412 generate an electrical signal. The electrical signal from an upward flex (e.g., as illustrated in FIG. 2) will be inverted compared with the signal of a downward flex. In some implementations, the signals from each piezoelectric cantilever 402 can be connected to the same signal path to combine the electrical signals from each piezoelectric cantilever 402 (e.g., shared bond pads 406). In other aspects, each piezoelectric cantilever 402 may have a separate signal path, allowing the signal from each piezoelectric cantilever 402 to be processed separately. In some aspects, groups of piezoelectric cantilevers 402 can be connected in different combinations. In some aspects, switching circuitry or groups of switches can be used to reconfigure the connections between multiple piezoelectric cantilevers 402 to provide different characteristics for different operating modes, such as transmit and receive modes.

In one aspect, adjacent piezoelectric cantilevers 402 can be alternately connected to separate electrical paths, such that every other piezoelectric cantilever 402 share a path. The electrical connections in such a configuration can be flipped to create a differential signal. Such an aspect can operate such that when an acoustic signal incident on a piezoelectric MEMS acoustic transducer causes all the cantilevers 402 to flex upward, half of the cantilevers 402 create a positive signal, and half the cantilevers 402 create a negative signal. The two separate signals can then be connected to opposite inverting and non-inverting ends of an amplifier of an analog front end. Similarly, when the same acoustic vibration causes the cantilevers 402 to flex downward, the signals of the two groups will flip polarity, providing for a differential electrical signal from the piezoelectric MEMS acoustic transducer.

Alternatively, rather than alternating piezoelectric cantilevers 402 within a single piezoelectric MEMS transducer to create a differential signal, identical MEMS transducers can be placed across a shared acoustic port with the connections to the amplifier of an analog front-end reversed and coupled to different inverting and non-inverting inputs of a differential amplifier of the analog front-end to create the differential signal using multiple piezoelectric MEMS transducers.

The piezoelectric cantilevers 402 may also each include an anchor reinforcement member 420 (or anchor reinforcement) configured to improve high stress events. In some aspects, the anchor reinforcement member 420 may include a ductile material that is disposed over the top electrodes 410. For example, the anchor reinforcement member 420 may be disposed during a process step for depositing bond pads (e.g., the bond pads 406) on top of the top electrodes 410. In some cases, the anchor reinforcement member 420 is configured to reduce a strain based on a mechanical boundary condition between the body of the MEMS piezoelectric transducer 400 and the piezoelectric cantilever 402.

FIG. 4B illustrates a cross-sectional view of a MEMS piezoelectric transducer in accordance with some aspects of the disclosure. In particular, FIG. 4B shows an example cross-sectional view of one of the cantilevers 402 along lines A-A′.

The piezoelectric cantilever 402 can be fabricated by one or multiple layers of piezoelectric material interleaved between top electrodes 410, middle electrodes 412, and bottom electrodes 414. The piezoelectric layers 404 can be made using piezoelectric materials used in MEMS devices, such as one or more of aluminum nitride (AlN), aluminum scandium nitride (AlScN), zinc oxide (ZnO), or lead zirconate titanate (PZT). In some examples, the top electrodes 410 and/or middle electrodes 412 can be made using metal materials used in MEMS devices, such as one or more of molybdenum (Mo), platinum (Pt), nickel (Ni), and aluminum (Al), and/or any combination thereof. In some cases, the top electrodes 410, middle electrodes 412, and bottom electrodes 414 can be formed from a non-metal, such as doped polysilicon. In some implementations, the top electrodes 410 may cover only a portion of the piezoelectric cantilever 402, (e.g., from the fixed end to about one-third of the piezoelectric cantilever 402), in such cases where these areas generate electrical energy more efficiently within the piezoelectric layer 404 than the areas near the central end (e.g., the free movement end) of each piezoelectric cantilever 402. Specifically, high-stress concentration in areas near the fixed end induced by the incoming sound pressure is converted into an electrical signal by direct piezoelectric effect. In some aspects, a top electrode can be formed on the top surface of the piezoelectric cantilever and an electrical discontinuity (e.g., an etched lines) can electrically separate the top electrode in the sensing region from the electrode in the lever region. In this case, the electrode in the lever region may be referred to as a mechanical electrode and may provide rigidity without having any electrical effects by virtue of being electrically isolated.

In some aspects, the piezoelectric cantilevers 402 and corresponding layers (e.g., the top electrodes 410, middle electrodes 412, and bottom electrodes 414, and the piezoelectric layer 404) may be formed on a substrate 416 using various semiconductor processes.

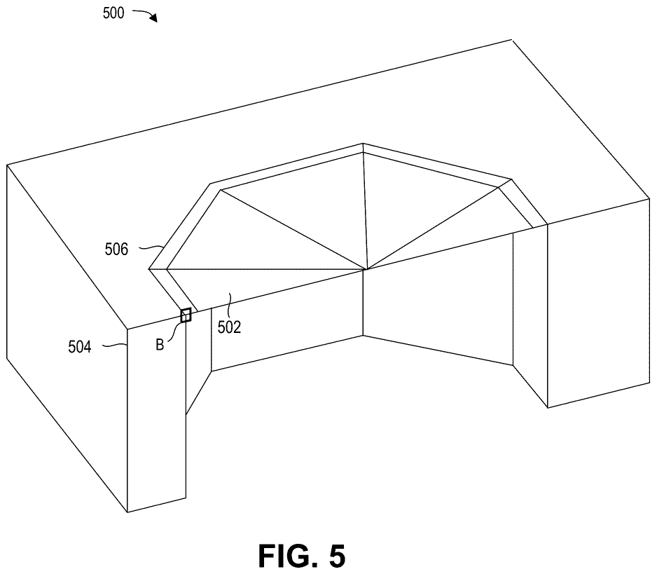

FIG. 5 is a perspective view of a cross-section of a piezoelectric MEMS sensor 500 (e.g., the MEMS piezoelectric transducer 400 in FIG. 4A) in accordance with some aspects of the disclosure. In some aspects, a boundary region B is illustrated between an edge of a piezoelectric cantilever 502 and a side surface 504. In some cases, the side surface can be a substrate. The side surface 504 may also be oxide material (e.g., SiO₂) formed over the substrate for various purposes. The boundary region may exhibit high stress based on mechanical force (e.g., acoustic signals or pressure) applied to the piezoelectric cantilever 506.

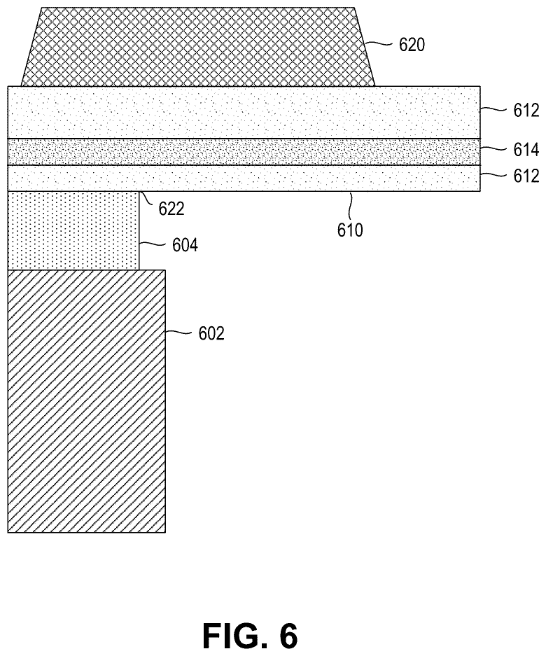

FIG. 6 illustrates an enlarged view of the boundary region between a side surface and a piezoelectric cantilever in accordance with some aspects of the disclosure. In particular, FIG. 6 illustrates an enlarged view of boundary region B in FIG. 5. A side surface 602 of the piezoelectric device may include an oxide layer 604 as described above.

A piezoelectric cantilever 610 may be formed on the oxide layer 604 (or the side surface 602). In some aspects, the cantilever 610 may include at least one piezoelectric layer 614 formed between conductive layers 612. The interleaved layers of the conductive layers 612 and the piezoelectric layer 614 may also be referred to as a MEMS stack and may include a plurality of piezoelectric layers interleaved with a corresponding barrier layer such as a conductive material.

In some aspects, an anchor reinforcement member 620 may be disposed over the piezoelectric cantilever 610. In some cases, the anchor reinforcement member 620 may be a ductile material as compared to the piezoelectric cantilever 610. The anchor reinforcement member 620 is partially disposed over the piezoelectric cantilever 610 and over the side surface 602 (e.g., in some cases, the anchor reinforcement member 620 may extend partially over the acoustic cavity). The side surface 602 may form a side surface of the piezoelectric device.

The anchor reinforcement member 620 is configured to spread a pressure that occurs at point 622. In some cases, when the anchor reinforcement member 620 bends, the bending of the anchor reinforcement member 620 will also cause a mechanical force to be applied to the anchor reinforcement member 620. The application of this mechanical force across the anchor reinforcement member 620 will disperse the stress that may normally be concentrated at point 622 based on the mechanical stresses.

In some aspects, the anchor reinforcement member 620 may have a thickness of a single micron. The thickness of the anchor reinforcement member 620 is selected to maintain the ductile properties of the anchor reinforcement member 620. In this example, the anchor reinforcement member 620 may be an aluminum material or compound. In other cases, the anchor reinforcement member 620 may be an aluminum-copper alloy that is deposited during the formation of bond pads. In this case, no additional extra process steps are required.

The length of the anchor reinforcement member 620 from a fixed point (e.g., the anchor region corresponding to the portion fixed to the oxide layer 604) to its distal point over the cavity is configured based on acoustic properties and failure probability. In some cases, a longer anchor reinforcement member 620 may improve reliability significantly. However, adding too much additional material at the base of the piezoelectric cantilever may increase the stiffness of the sensing region. Increases stiffness in the sensing region may limit the voltage generated in an electrode, and may reduce the detected signal power (e.g., signal strength). Decreasing the signal strength adversely affects acoustic performance such as SNR and dynamic range. In some cases, the length of the piezoelectric cantilever can be increased to reduce this effect of additional material in the anchor reinforcement member 620.

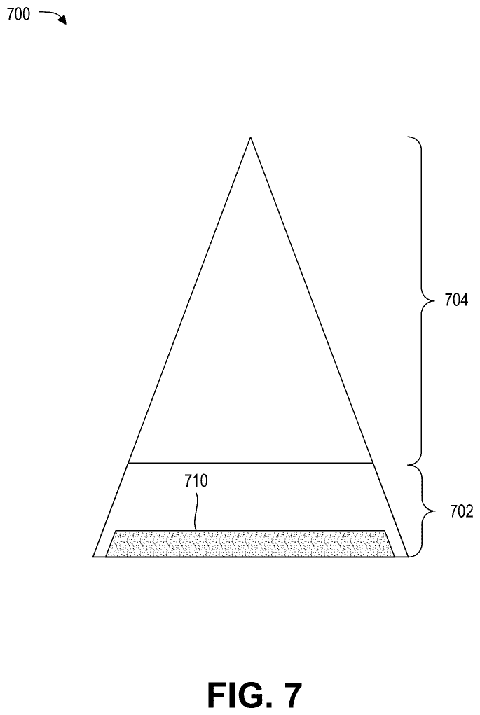

FIG. 7 illustrates a plan view of a piezoelectric cantilever 700 including an anchor reinforcement in accordance with some aspects of the disclosure. In some aspects, the piezoelectric cantilever 700 is divided into a sensing region 702 and a lever region 704. The sensing region 702 includes an electrode for converting charge into a voltage signal.

An anchor reinforcement member 710 is disposed at the base of the piezoelectric cantilever 700 and substantially covers the lateral width of the piezoelectric cantilever 700. For example, a gap between the anchor reinforcement member 710 and a lateral edge of the piezoelectric cantilever 700 is provided to facilitate various additional semiconductor processes (e.g., etching).

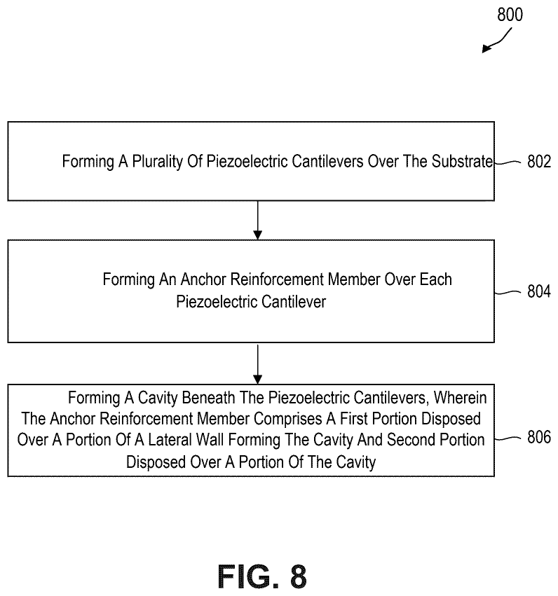

FIG. 8 illustrates a method 800 for forming a MEMS transducer including a piezoelectric cantilever with an anchor reinforcement member in accordance with some aspects of the disclosure.

At block 802, the method 800 includes forming a plurality of piezoelectric cantilevers over the substrate.

At block 804, the method 800 includes forming an anchor reinforcement member over each piezoelectric cantilever. For example, the anchor reinforcement may be formed in a process step associated with forming bond pads of a piezoelectric device.

At block 806, the method 800 includes forming a cavity beneath the piezoelectric cantilevers. In some aspects, the anchor reinforcement member comprises a first portion disposed over a portion of a lateral wall forming the cavity and a second portion disposed over a portion of the cavity.

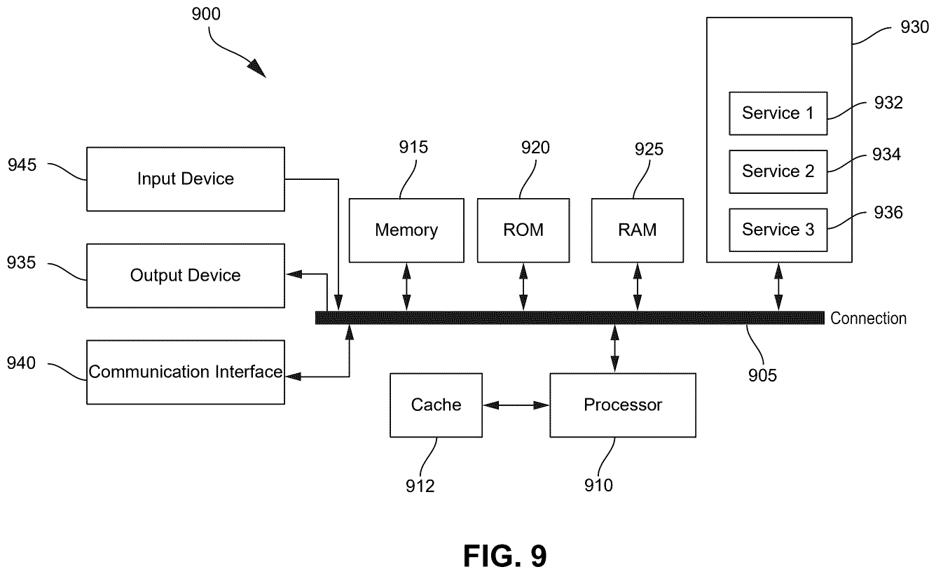

FIG. 9 is a diagram illustrating an example of a system for implementing certain aspects of the present technology. In particular, FIG. 9 illustrates an example of computing system 900 which can include MEMS transducers or devices including MEMS devices having piezoelectric cantilevers with an anchor reinforcement member in accordance with aspects described herein. An acoustic transducer can be integrated, for example, with any computing device making up internal computing system, a remote computing system, a camera, or any component thereof in which the components of the system are in communication with each other using connection 905. Connection 905 may be a physical connection using a bus, or a direct connection into processor 910, such as in a chipset architecture. Connection 905 may also be a virtual connection, networked connection, or logical connection.

Example computing system 900 includes at least one processing unit (CPU or processor) 910 and connection 905 that communicatively couples various system components including system memory 915, such as read-only memory (ROM) 920 and random access memory (RAM) 925 to processor 910. Computing system 900 may include a cache 912 of high-speed memory connected directly with, in close proximity to, or integrated as part of processor 910.

Processor 910 may include any general purpose processor and a hardware service or software service, such as services 932, 934, and 936 stored in storage device 930, configured to control processor 910 as well as a special-purpose processor where software instructions are incorporated into the actual processor design. Processor 910 may essentially be a completely self-contained computing system, containing multiple cores or processors, a bus, memory controller, cache, etc. A multi-core processor may be symmetric or asymmetric.

To enable user interaction, computing system 900 includes an input device 945, which may represent any number of input mechanisms, such as a microphone for speech or audio detection (e.g., PZ MEMS transducer or a MEMS transducer system in accordance with aspects described above, etc.) along with other input devices 945 such as a touch-sensitive screen for gesture or graphical input, keyboard, mouse, motion input, speech, etc. Computing system 900 may also include output device 935, which may be one or more of a number of output mechanisms. In some instances, multimodal systems may enable a user to provide multiple types of input/output to communicate with computing system 900.

Computing system 900 may include communications interface 940, which may generally govern and manage the user input and system output. The communication interface may perform or facilitate receipt and/or transmission wired or wireless communications using wired and/or wireless transducers, including those making use of an audio jack/plug, a microphone jack/plug, a universal serial bus (USB) port/plug, an Apple™ Lightning™ port/plug, an Ethernet port/plug, a fiber optic port/plug, a proprietary wired port/plug, 3G, 4G, 5G and/or other cellular data network wireless signal transfer, a Bluetooth™ wireless signal transfer, a Bluetooth™ low energy (BLE) wireless signal transfer, an IBEACON™ wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof. The communications interface 940 may also include one or more Global Navigation Satellite System (GNSS) receivers or transducers that are used to determine a location of the computing system 900 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 930 may be a non-volatile and/or non-transitory and/or computer-readable memory device and may be a hard disk or other types of computer readable media which may store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (e.g., Level 1(L 1 ) cache, Level 2(L 2 ) cache, Level 3(L 3 ) cache, Level 4(L 4 ) cache, Level 5(L 5 ) cache, or other (L #) cache), resistive random-access memory (RRAM/ReRAM), phase change memory (PCM), spin transfer torque RAM (STT-RAM), another memory chip or cartridge, and/or a combination thereof.

The storage device 930 may include software services, servers, services, etc., that when the code that defines such software is executed by the processor 910, it causes the system to perform a function. In some embodiments, a hardware service that performs a particular function may include the software component stored in a computer-readable medium in connection with the necessary hardware components, such as processor 910, connection 905, output device 935, etc., to carry out the function. The term “computer-readable medium” includes, but is not limited to, portable or non-portable storage devices, optical storage devices, and various other mediums capable of storing, containing, or carrying instructions(s) and/or data. A computer-readable medium may include a non-transitory medium in which data may be stored and that does not include carrier waves and/or transitory electronic signals propagating wirelessly or over wired connections. Examples of a non-transitory medium may include, but are not limited to, a magnetic disk or tape, optical storage media such as compact disk (CD) or digital versatile disk (DVD), flash memory, memory or memory devices. A computer-readable medium may have stored thereon code and/or machine-executable instructions that may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, or the like.

Specific details are provided in the description above to provide a thorough understanding of the embodiments and examples provided herein, but those skilled in the art will recognize that the application is not limited thereto. Thus, while illustrative embodiments of the application have been described in detail herein, it is to be understood that the inventive concepts may be otherwise variously embodied and employed, and that the appended claims are intended to be construed to include such variations, except as limited by the prior art. Various features and aspects of the above-described application may be used individually or jointly. Further, embodiments may be utilized in any number of environments and applications beyond those described herein without departing from the broader scope of the specification. The specification and drawings are, accordingly, to be regarded as illustrative rather than restrictive. For the purposes of illustration, methods were described in a particular order. It should be appreciated that in alternate embodiments, the methods may be performed in a different order than that described.

For clarity of explanation, in some instances the present technology may be presented as including individual functional blocks including devices, device components, steps or routines in a method embodied in software, or combinations of hardware and software. Additional components may be used other than those shown in the figures and/or described herein. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail in order to avoid obscuring the embodiments.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Individual embodiments may be described above as a process or method which is depicted as a flowchart, a flow diagram, a data flow diagram, a structure diagram, or a block diagram. Although a flowchart may describe the operations as a sequential process, many of the operations may be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination may correspond to a return of the function to the calling function or the main function.

Processes and methods according to the above-described examples may be implemented using computer-executable instructions that are stored or otherwise available from computer-readable media. Such instructions may include, for example, instructions and data which cause or otherwise configure a general purpose computer, special purpose computer, or a processing device to perform a certain function or group of functions. Portions of computer resources used may be accessible over a network. The computer executable instructions may be, for example, binaries, intermediate format instructions such as assembly language, firmware, source code. Examples of computer-readable media that may be used to store instructions, information used, and/or information created during methods according to described examples include magnetic or optical disks, flash memory, USB devices provided with non-volatile memory, networked storage devices, and so on.

In some embodiments the computer-readable storage devices, mediums, and memories may include a cable or wireless signal containing a bitstream and the like. However, when mentioned, non-transitory computer-readable storage media expressly exclude media such as energy, carrier signals, electromagnetic waves, and signals per se.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof, in some cases depending in part on the particular application, in part on the desired design, in part on the corresponding technology, etc.

The various illustrative logical blocks, modules, and circuits described in connection with the aspects disclosed herein may be implemented or performed using hardware, software, firmware, middleware, microcode, hardware description languages, or any combination thereof, and may take any of a variety of form factors. When implemented in software, firmware, middleware, or microcode, the program code or code segments to perform the necessary tasks (e.g., a computer-program product) may be stored in a computer-readable or machine-readable medium. A processor(s) may perform the necessary tasks. Examples of form factors include laptops, smart phones, mobile phones, tablet devices or other small form factor personal computers, personal digital assistants, rackmount devices, standalone devices, and so on. Functionality described herein also may be embodied in peripherals or add-in cards. Such functionality may also be implemented on a circuit board among different chips or different processes executing in a single device, by way of further example.

The instructions, media for conveying such instructions, computing resources for executing them, and other structures for supporting such computing resources are example means for providing the functions described in the disclosure.

The techniques described herein may also be implemented in electronic hardware, computer software, firmware, or any combination thereof. Such techniques may be implemented in any of a variety of devices such as general purpose computers, wireless communication device handsets, or integrated circuit devices having multiple uses including application in wireless communication device handsets and other devices. Any features described as modules or components may be implemented together in an integrated logic device or separately as discrete but interoperable logic devices. If implemented in software, the techniques may be realized at least in part by a computer-readable data storage medium including program code including instructions that, when executed, performs one or more of the methods, algorithms, and/or operations described above. The computer-readable data storage medium may form part of a computer program product, which may include packaging materials. The computer-readable medium may include memory or data storage media, such as random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The techniques additionally, or alternatively, may be realized at least in part by a computer-readable communication medium that carries or communicates program code in the form of instructions or data structures and that may be accessed, read, and/or executed by a computer, such as propagated signals or waves.

The program code may be executed by a processor, which may include one or more processors, such as one or more digital signal processors (DSPs), general purpose microprocessors, an application specific integrated circuits (ASICs), field programmable logic arrays (FPGAs), or other equivalent integrated or discrete logic circuitry. Such a processor may be configured to perform any of the techniques described in this disclosure. A general-purpose processor may be a microprocessor; but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Accordingly, the term “processor,” as used herein may refer to any of the foregoing structure, any combination of the foregoing structure, or any other structure or apparatus suitable for implementation of the techniques described herein.

Where components are described as being “configured to” perform certain operations, such configuration may be accomplished, for example, by designing electronic circuits or other hardware to perform the operation, by programming programmable electronic circuits (e.g., microprocessors, or other suitable electronic circuits) to perform the operation, or any combination thereof.

The phrase “coupled to” or “communicatively coupled to” refers to any component that is physically connected to another component either directly or indirectly, and/or any component that is in communication with another component (e.g., connected to the other component over a wired or wireless connection, and/or other suitable communication interface) either directly or indirectly.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, A and B and C, or any duplicate information or data (e.g., A and A, B and B, C and C, A and A and B, and so on), or any other ordering, duplication, or combination of A, B, and C. The language “at least one of” a set and/or “one or more” of a set does not limit the set to the items listed in the set. For example, claim language reciting “at least one of A and B” or “at least one of A or B” may mean A, B, or A and B, and may additionally include items not listed in the set of A and B. The phrases “at least one” and “one or more” are used interchangeably herein.

Claim language or other language reciting “at least one processor configured to,” “at least one processor being configured to,” “one or more processors configured to,” “one or more processors being configured to,” or the like indicates that one processor or multiple processors (in any combination) can perform the associated operation(s). For example, claim language reciting “at least one processor configured to: X, Y, and Z” means a single processor can be used to perform operations X, Y, and Z; or that multiple processors are each tasked with a certain subset of operations X, Y, and Z such that together the multiple processors perform X, Y, and Z; or that a group of multiple processors work together to perform operations X, Y, and Z. In another example, claim language reciting “at least one processor configured to: X, Y, and Z” can mean that any single processor may only perform at least a subset of operations X, Y, and Z.

Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions.

Where reference is made to an entity (e.g., any entity or device described herein) performing functions or being configured to perform functions (e.g., steps of a method), the entity may be configured to cause one or more elements (individually or collectively) to perform the functions. The one or more components of the entity may include at least one memory, at least one processor, at least one communication interface, another component configured to perform one or more (or all) of the functions, and/or any combination thereof. Where reference to the entity performing functions, the entity may be configured to cause one component to perform all functions, or to cause more than one component to collectively perform the functions. When the entity is configured to cause more than one component to collectively perform the functions, each function need not be performed by each of those components (e.g., different functions may be performed by different components) and/or each function need not be performed in whole by only one component (e.g., different components may perform different sub-functions of a function).

A number of implementations have been described. Nevertheless, it will be understood that various modifications may be made without departing from the spirit and scope of the disclosure. Other embodiments are within the scope of the claims.

Illustrative aspects of the disclosure include:
Aspect 1. A MEMS transducer, comprising: a transducer body including an acoustic cavity extending from a bottom surface to a top surface; a piezoelectric cantilever disposed over the top surface and including a lever region and a sensing region; and an anchor reinforcement member disposed over the piezoelectric cantilever and the transducer body.
Aspect 2. The MEMS transducer of Aspect 1, wherein the piezoelectric cantilever is disposed over the top surface of the transducer body.
Aspect 3. The MEMS transducer of any of Aspects 1 to 2, wherein the anchor reinforcement member comprises a ductile material.
Aspect 4. The MEMS transducer of any of Aspects 1 to 3, wherein the anchor reinforcement member comprises a conductive material.
Aspect 5. The MEMS transducer of Aspect 4, wherein a thickness of the conductive material is approximately 1 micron.
Aspect 6. The MEMS transducer of any of Aspects 1 to 5, wherein the anchor reinforcement member is formed in a process step for forming bond pads.
Aspect 7. The MEMS transducer of any of Aspects 1 to 6, wherein the anchor reinforcement member reduces a probability of failure in response to an acoustic event.
Aspect 8. The MEMS transducer of any of Aspects 1 to 7, wherein a first portion of the anchor reinforcement member is disposed on a based over a side surface of the transducer body and a second portion of the anchor reinforcement member is disposed over a cavity.
Aspect 9. The MEMS transducer of Aspect 8, wherein the anchor reinforcement member distributes stress at an intersection point between the piezoelectric cantilever and the transducer body.
Aspect 10. The MEMS transducer of any of Aspects 1 to 9, wherein a length of the anchor reinforcement member in a lengthwise direction of the piezoelectric cantilever corresponds to a failure rate.
Aspect 11. An apparatus, comprising: a microelectromechanical system (MEMS) transducer for generating an electrical signal based on acoustic signals, wherein the MEMS transducer includes: a transducer body including an acoustic cavity extending from a bottom surface to a top surface; a piezoelectric cantilever disposed over the top surface and including a lever region and a sensing region; and an anchor reinforcement member disposed over the piezoelectric cantilever and the transducer body.
Aspect 12. The apparatus of Aspect 11, wherein the piezoelectric cantilever is disposed over the top surface of the transducer body.
Aspect 13. The apparatus of any of Aspects 11 to 12, wherein the anchor reinforcement member comprises a ductile material.
Aspect 14. The apparatus of any of Aspects 11 to 13, wherein the anchor reinforcement member comprises a conductive material.
Aspect 15. The apparatus of Aspect 14, wherein a thickness of the conductive material is approximately 1 micron.
Aspect 16. The apparatus of any of Aspects 11 to 15, wherein the anchor reinforcement member is formed in a process step for forming bond pads.
Aspect 17. The apparatus of any of Aspects 11 to 16, wherein the anchor reinforcement member reduces a probability of failure in response to an acoustic event.
Aspect 18. The apparatus of any of Aspects 11 to 17, wherein a first portion of the anchor reinforcement member is disposed on a based over a side surface of the transducer body and a second portion of the anchor reinforcement member is disposed over a cavity.
Aspect 19. The apparatus of Aspect 18, wherein the anchor reinforcement member distributes stress at an intersection point between the piezoelectric cantilever and the transducer body.
Aspect 20. A method of fabricating a microelectromechanical system (MEMS) transducer, comprising: forming a protective layer over a substrate; forming a plurality of piezoelectric cantilevers over the substrate; forming an anchor reinforcement member over each piezoelectric cantilever; and forming a cavity beneath the plurality of piezoelectric cantilevers, wherein the anchor reinforcement member comprises a first portion disposed over a portion of a lateral wall forming the cavity and second portion disposed over a portion of the cavity.
Aspect 21. An acoustic transducer, comprising: a substrate having a top surface and forming an acoustic cavity; a piezoelectric electroacoustic structure including at least one cantilever beam with a base coupled to the top surface of the substrate and extending over the acoustic cavity, the cantilever beam formed from a layer stack comprising one or more alternating electrode layers and piezoelectric layers; and a layer of ductile material disposed on or above the piezoelectric electroacoustic structure and disposed over the top surface of the substrate and extending partially over the acoustic cavity.
Aspect 22. The acoustic transducer of Aspect 21, wherein the ductile material is aluminum.
Aspect 23. The acoustic transducer of any of Aspects 21 to 22, wherein the layer of ductile material extends over the acoustic cavity by an amount that is less than 10% of a total length of the cantilever beam in a direction extending from the base to the tip.
Aspect 24. The acoustic transducer of any of Aspects 21 to 23, wherein the layer of ductile material extends over the acoustic cavity by an amount that is less than a total length of the cantilever beam in a direction extending from the base to the tip.

What is claimed is:

1. A microelectromechanical system (MEMS) transducer, comprising:
a transducer body including an acoustic cavity extending from a bottom surface to a top surface;
a piezoelectric cantilever disposed over the top surface and including a lever region and a sensing region; and
an anchor reinforcement member disposed over the piezoelectric cantilever and the transducer body.

2. The MEMS transducer of claim 1, wherein the piezoelectric cantilever is disposed over the top surface of the transducer body.

3. The MEMS transducer of claim 1, wherein the anchor reinforcement member comprises a ductile material.

4. The MEMS transducer of claim 1, wherein the anchor reinforcement member comprises a conductive material.

5. The MEMS transducer of claim 4, wherein a thickness of the conductive material is approximately 1 micron.

6. The MEMS transducer of claim 1, wherein the anchor reinforcement member is formed in a process step for forming bond pads.

7. The MEMS transducer of claim 1, wherein the anchor reinforcement member reduces a probability of failure in response to an acoustic event.

8. The MEMS transducer of claim 1, wherein a first portion of the anchor reinforcement member is disposed on a base over a side surface of the transducer body and a second portion of the anchor reinforcement member is disposed over a cavity.

9. The MEMS transducer of claim 8, wherein the anchor reinforcement member distributes stress at an intersection point between the piezoelectric cantilever and the transducer body.

10. The MEMS transducer of claim 1, wherein a length of the anchor reinforcement member in a lengthwise direction of the piezoelectric cantilever contributes to a failure probability.

11. An apparatus, comprising:
a microelectromechanical system (MEMS) transducer for generating an electrical signal based on acoustic signals,
wherein the MEMS transducer includes:
a transducer body including an acoustic cavity extending from a bottom surface to a top surface;
a piezoelectric cantilever disposed over the top surface and including a lever region and a sensing region; and
an anchor reinforcement member disposed over the piezoelectric cantilever and the transducer body.

12. The apparatus of claim 11, wherein the piezoelectric cantilever is disposed over the top surface of the transducer body.

13. The apparatus of claim 11, wherein the anchor reinforcement member comprises a ductile material.

14. The apparatus of claim 11, wherein the anchor reinforcement member comprises a conductive material.

15. The apparatus of claim 14, wherein a thickness of the conductive material is approximately 1 micron.

16. The apparatus of claim 11, wherein the anchor reinforcement member is formed in a process step for forming bond pads.

17. The apparatus of claim 11, wherein the anchor reinforcement member reduces a probability of failure in response to an acoustic event.

18. The apparatus of claim 11, wherein a first portion of the anchor reinforcement member is disposed on a base over a side surface of the transducer body and a second portion of the anchor reinforcement member is disposed over a cavity.

19. The apparatus of claim 18, wherein the anchor reinforcement member distributes stress at an intersection point between the piezoelectric cantilever and the transducer body.

20. An acoustic transducer, comprising:
a substrate having a top surface and forming an acoustic cavity;
a piezoelectric electroacoustic structure including at least one cantilever beam with a base coupled to the top surface of the substrate and extending over the acoustic cavity, the at least one cantilever beam formed from a layer stack comprising one or more alternating electrode layers and piezoelectric layers; and
a layer of ductile material disposed on or above the piezoelectric electroacoustic structure and disposed over the top surface of the substrate and extending partially over the acoustic cavity.
